(19) United States
(12) Patent Application Publication
(10) Pub. No.: US 2008/0011455 A1
(43) Pub. Date: Jan. 17, 2008

(54) Composite heat-dissipating module

(75) Inventors: Alex Horng, Kaohsiung (TW); Masaharu Miyahara, Kaohsiung (TW)

Correspondence Address: BIRCH STEWART KOLASCH & BIRCH, PO BOX 747, FALLS CHURCH, VA, 22040-0747, US

(73) Assignee: Sunonwealth Electric Machine Industry Co., Ltd.

(21) Appl. No.: 11/487,308

(22) Filed: Jul. 17, 2006

(51) Int. Cl. H05K 7/20

(52) U.S. Cl. 165/80.4; 361/698

(57) ABSTRACT

A composite heat-dissipating module includes a base, at least one fin unit, a stirring unit, and at least two horizontal air-feeding units. The base includes a top face, a bottom face, and a compartment. The bottom face is in contact with an object to be heat-dissipated. A heat-conducting liquid is received in the compartment. The fin unit is mounted on the top face of the base. The fin unit includes a plurality of fins. A heat-dissipating channel is defined between a pair of the fins adjacent to each other. A stirring unit stirs the heat-conducting liquid to circulate the heat-conducting liquid in the compartment. The horizontal air-feeding units are mounted on at least one side of the fin unit. The horizontal air-feeding units provide lateral airflows into the heat-dissipating channels for dissipating heat.

### BACKGROUND OF THE INVENTION

1. Field of the Invention

The present invention relates to heat-dissipating module. More particularly, the present invention relates to a composite heat-dissipating module providing dual heat-dissipating effect.

2. Description of Related Art

Taiwan Utility Model Publication No. 584269 discloses a heat-dissipating fin apparatus containing liquid to be stirred. Referring to FIG. 1 of the accompanying drawings, the heat-dissipating fin apparatus comprises a base 91, a fin unit 92, a fan 93, a compartment 94, a driving device 95, and a stirring member 96. The base 91 is in contact with a heat-generating component 90. The fin unit 92 includes a plurality of fins mounted on the base 91 and spaced at regular intervals. The fan 93 is fixed on top of the fins for driving air currents to flow downward. The compartment 94 is defined in the base 91 and receives a heat-conducting liquid. The driving device 95 is mounted above the compartment 94 and adjacent to the fin unit 92. The stirring member 96 is mounted in the compartment 94 and connected to the driving device 95 by a shaft 97. In operation, the base 91 absorbs heat generated by the heat-generating component 90 and transfers the heat to the fin unit 92 and the heat-conducting liquid in the compartment 94. Meanwhile, the fan 93 drives air currents to dissipate heats of the fin unit 92 and the base 91. The driving device 95 turns the stirring member 96 to stir the heat-conducting liquid in the compartment 94. Thus, dual heat-dissipating effect including air cooling and liquid cooling is provided synchronously.

However, the overall height of the above-mentioned composite heat-dissipating module is increased by the fan 93 mounted on top of the fin unit 92. As a result, the composite heat-dissipating module cannot be used in compact electronic devices such as notebook type computers, desktop type computers, barebone computers, etc. Further, in a case that the overall area of the composite heat-dissipating module is increased for dissipating heats of several heat-generating components or a large heat-generating component, a larger fan 93 must be used, leading to further increase in the overall height of the composite heat-dissipating module. Further, the airflow driven by the fan 93 directly contacts the driving device 95 and causes turbulence nearby. Noise is thus generated. Further, the airflow direction could not be effectively controlled, failing to satisfy various needs of various electronic devices.

Further, more electrical energy is consumed for using the driving device 95 to drive the stirring member 96. Although another embodiment disclosed in Taiwan Utility Model Publication No. 584269 uses the fan 93 to drive the stirring member 96 without using the driving device 95, the speed and the driving efficiency are reduced. Further, if the stirring member 96 turns too fast, wear to the circumferential wall defining a hole through which the shaft 97 extends is increased, resulting in a risk of leakage of the heat-conducting liquid.

### OBJECTS OF THE INVENTION

An object of the present invention is to provide a composite heat-dissipating module that has a reduced overall height and that has an increased overall area.

Another object of the present invention is to provide a composite heat-dissipating module that is flexible in the various designs and thus has wider application.

A further object of the present invention is to provide a composite heat-dissipating module without the risk of leakage of heat-conducting liquid.

Still another object of the present invention is to provide a composite heat-dissipating module that consumes less electrical energy and that has a simplified structure.

Yet another object of the present invention is to provide a composite heat-dissipating module that avoids generation of turbulence and noise.

### SUMMARY OF THE INVENTION

A composite heat-dissipating module in accordance with the present invention comprises a base, at least one fin unit, a stirring unit, and at least two horizontal air-feeding units. The base comprises a top face, a bottom face, and a compartment. The bottom face is adapted to contact with an object to be heat-dissipated. A heat-conducting liquid is received in the compartment. The at least one fin unit is mounted on the top face of the base. The at least one fin unit includes a plurality of fins. A heat-dissipating channel is defined between a pair of the fins adjacent to each other. A stirring unit stirs the heat-conducting liquid to circulate the heat-conducting liquid in the compartment. The at least two horizontal air-feeding units are mounted on at least one side of the at least one fin unit. The at least two horizontal air-feeding units provide lateral airflows into the heat-dissipating channels for dissipating heat.

The at least two horizontal air-feeding units may be mounted to the same side of the at least one fin unit.

Alternatively, the at least two horizontal air-feeding units are mounted to different sides of the at least one fin unit and the airflows driven by the at least two horizontal air-feeding units flow through different portions of the at least one fin unit.

The at least two horizontal air-feeding units may be selected from at least one of axial flow fans and blower fans.

Preferably, the stirring unit is mounted in the compartment.

A driving member may be mounted on the top face of the base for indirectly driving the stirring unit.

In an example, the stirring unit is an impeller including a shaft rotatably coupled to an inner wall of the base and the impeller is aligned with the driving member.

The driving member may be a motor comprising a stator and a rotor. The stator includes at least one coil and at least one pole plate. The rotor includes at least one magnet.

Preferably, the stirring unit comprises an actuating plate. At least one magnetically inductive member is mounted on the actuating plate and aligned with the magnet of the rotor.

Preferably, the magnetically inductive member is made of magnetic material or magnetically conductive material.

In another example, the driving member is an impeller of blower type or axial flow type. The driving member includes a magnet for driving the stirring unit by magnetic attraction.

Preferably, the stirring unit is an impeller including a shaft rotatably coupled to an inner wall of the base. The impeller includes a magnet aligned with the magnet on the driving member.

In an example, the driving unit is driven by a portion of lateral horizontal airflow driven by at least one of the at least, two horizontal air-feeding units.

In another example, the fins define a space in which the driving unit is mounted. The driving unit is driven by a portion of lateral horizontal airflow driven by at least one of the at least two horizontal air-feeding units that flows through the space.

Preferably, the least one wall defining the compartment of the base includes a plurality of concave portions and/or a plurality of convex portions to increase a heat-exchange area between said at lease one wall and the heat-conducting liquid.

Other objects, advantages and novel features of this invention will become more apparent from the following detailed description when taken in conjunction with the accompanying drawings.

### BRIEF DESCRIPTION OF THE DRAWINGS

FIG. 1 is a sectional view illustrating a conventional composite heat-dissipating module;

FIG. 2 is a perspective view of a first embodiment of a composite heat-dissipating module in accordance with the present invention;

FIG. 3 is a sectional view of the composite heat-dissipating module in FIG. 2;

FIG. 4 is a sectional view taken along plane 4-4 in FIG. 3;

FIG. 5 is a sectional view illustrating a second embodiment of the composite heat-dissipating module in accordance with the present invention; and

FIG. 6 is a perspective view of a third embodiment of the composite heat-dissipating module in accordance with the present invention.

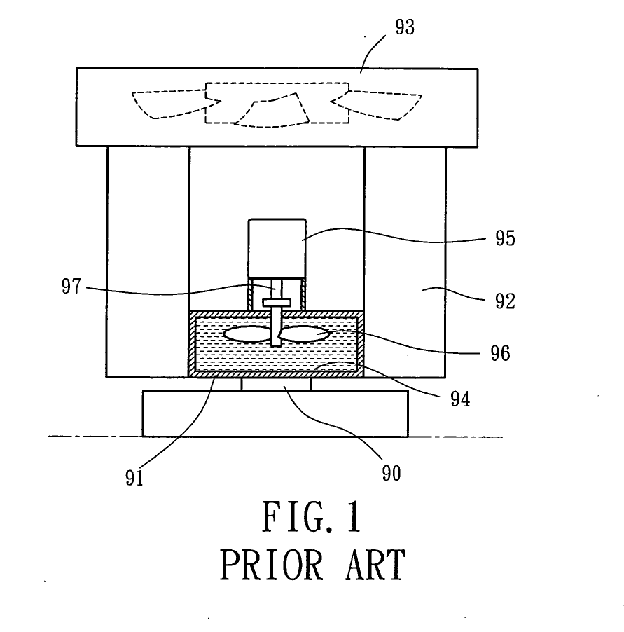

### DETAILED DESCRIPTION OF THE PREFERRED EMBODIMENTS

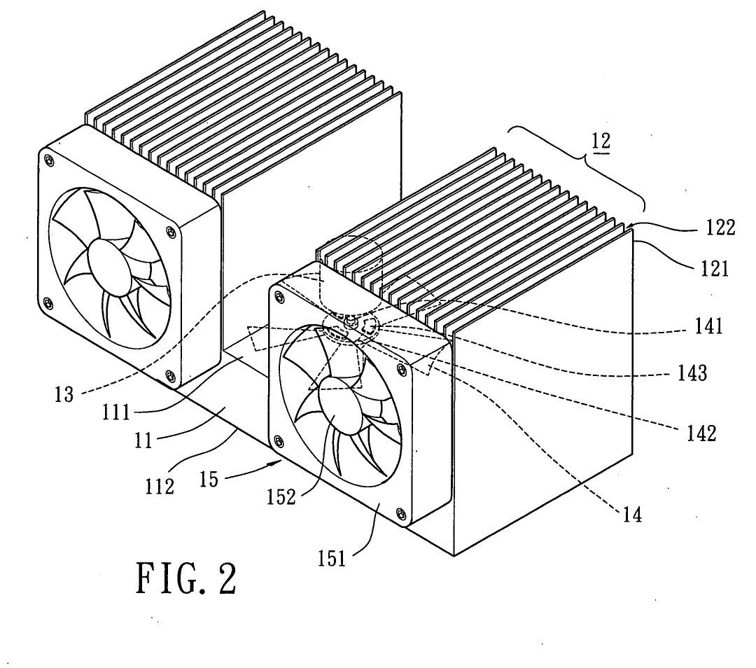

Referring to FIG. 2, a first embodiment of a composite heat-dissipating module in accordance with the present invention comprises a base 11, at least one fin unit 12 (two in this embodiment), a driving unit 13, a stirring unit 14, and at least two horizontal air-feeding units 15. The composite heat-dissipating module is used to dissipate heats of at least one object 10 (three in this example) by air cooling and liquid cooling synchronously. The composite heat-dissipating module can be mounted in a notebook type or desktop type computer or in a casing for barebone computers or other electronic devices. The objects 10 to be heat-dissipated may be high-power integrated circuits, displays, or electronic components, such as CPUs, liquid crystal displays, or the processing chips for display cards, drawing cards, or other interface cards. Nevertheless, the composite heat-dissipating module in accordance with the present invention is not limited to the above-mentioned fields, and the objects 10 to be heat-dissipated is not limited to the above. The composite heat-dissipating module in accordance with the present invention can be used in any electronic device that requires heat-dissipation.

Referring to FIGS. 2, 3, and 4, the base 11 in the first embodiment is made of a material with excellent thermal conductivity, such as copper, aluminum, gold, silver, and alloys thereof. The base 11 includes a top face 111, a bottom face 112, and a compartment 110. The fin units 12 and the driving unit 13 are mounted on the top face 111. The bottom face 112 is in contact with the objects 10 to be heat-dissipated. The compartment 110 receives the stirring unit 14 and a heat-conducting liquid that is water or a coolant with high thermal conductivity.

Still referring to FIGS. 2, 3, and 4, the fin units 12 in the first embodiment is made of a material with excellent thermal conductivity, such as copper, aluminum, gold, silver, and alloys thereof. The fin units 12 are integrally formed with the base 11. Alternatively, the fin units 12 and the base 11 are manufactured separately and then coupled together by snapping, screwing, gluing, welding, or insertion. Each fin unit 12 includes a plurality of spaced fins 121. A heat-dissipating channel 122 is defined between a pair of fins 121 adjacent to each other. Each heat-dissipating channel 122 has an outlet (not labeled) and an inlet (not labeled) on opposite sides of the respective fin units 12 for guiding lateral input and lateral output of horizontal airflows.

Still referring to FIGS. 2, 3, and 4, the driving unit 13 in the first embodiment is mounted between the fin units 12. Preferably, the driving unit 13 is a motor including a stator 131 and a rotor 132 that are preferably mounted in a motor casing (not labeled). The stator 131 includes at least one coil (not labeled) and at least one pole plate (not labeled). The rotor 132 includes at least one magnet 133. Electric current can be supplied to the coil of the stator 131 to cause the pole plate to create alternating magnetic field. The magnet 133 induces the alternating magnetic field and drives the rotor 132 to turn.

Still referring to FIGS. 2, 3, and 4, the stirring unit 14 in the first embodiment is preferably an impeller including a shaft 141 rotatably coupled to an inner wall of the base 11. The stirring unit 14 aligns with the driving unit 13. An actuating plate 142 is fixed to the stirring unit 14 and at least one magnetically inductive member 143 is mounted on the actuating plate 142. The magnetically inductive member 143 is made of magnetic material (such as a magnet) or magnetically conductive material (such as iron or iron alloy). The magnetically inductive member 143 indirectly aligns with the magnet 133 of the rotor 132 of the driving unit 13. Hence, when the magnet 133 of the rotor 132 turns, the magnetically inductive member 143 is turned by mutual magnetic attraction between the magnet 133 and the magnetically inductive member 143, thereby driving the stirring unit 14. Thus, the heat-conducting liquid in the compartment 110 is stirred and flows in the compartment 110 in a circulating manner.

Still referring to FIGS., 2, 3, and 4, the at least two horizontal air-feeding units 15 are preferably axial flow fans. Nevertheless, the horizontal air-feeding units 15 may be blower fans. Each horizontal air-feeding unit 15 includes a casing 151 and an impeller 152. The casing 151 is fixed to at least one side of the at least one fin unit 12 by snapping, screwing, gluing, welding, or insertion. In this embodiment, the at least two casings 151 are preferably fixed on the same side of the at least one fin unit 12. The impeller 152 is rotatably received in the associated casing 151 for generating an airflow (not shown).

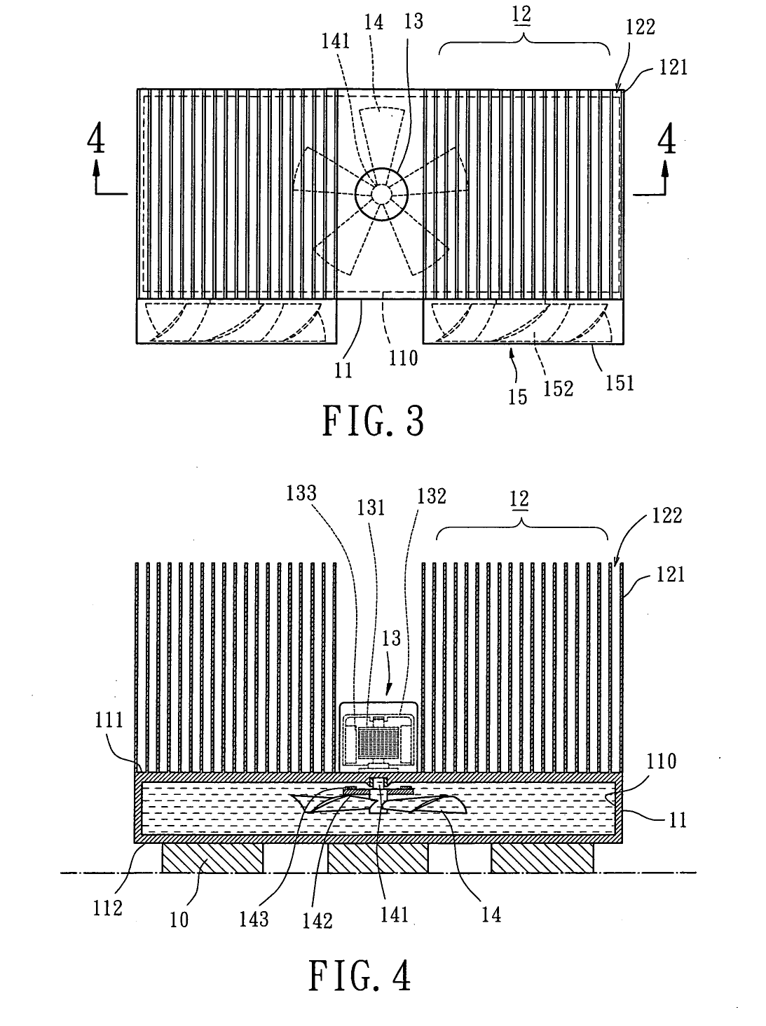

Referring to FIGS. 3 and 4, when the composite heat-dissipating module of the first embodiment is used to dissipate heats of the objects 10, the bottom face 112 of the base 11 absorbs heat energy generated by the objects 10. The heat energy is transferred to the heat-conducting liquid in the compartment 110. The heat-conducting liquid is stirred by the stirring unit 14 driven by the driving member 13, allowing the heat energy to be rapidly transferred to each fin 121. Meanwhile, the impellers 152 of the at least two horizontal air-feeding units 15 rotate and generate airflows that are guided into the heat-dissipating channels 122 of the fin units 12 for proceeding with air cooling of the fins 121.

In the composite heat-dissipating module of the first embodiment in accordance with the present invention, the overall height is reduced by fixing the casings 151 of the at least two horizontal air-feeding units 15 on the same side of the fin units 12 without affecting the height of the fins 121. Meanwhile, the overall area of the base 11 can be increased to a desired extent for mounting more horizontal air-feeding units 15 for the purposes of dissipating heats of more objects or dissipating heats of a large object without increasing the overall height of the composite heat-dissipating module. Thus, the application of the composite heat-dissipating module is wider and the design flexibility of the composite heat-dissipating module is increased, allowing use in the casings of various electronic devices that are becoming more and more compact.

Mounting the casings 151 of the horizontal air-feeding units 15 on the same side of at least one fin unit 12 also provide at least two airflows that flow in the same direction for cooling at least one fin unit 12, which is advantageous to control the input direction and the output direction of the airflows, avoiding recycling of the output airflows. The heat-dissipating efficiency of air cooling is thus enhanced. Further, the driving member 13 can be mounted outside the compartment 110 to indirectly driving the stirring unit 14 by magnetic attraction between the magnet 133 on the driving member 13 and the magnetically inductive member 143 on the stirring unit 14. The sealing reliability is enhanced and leakage of the heat-conducting liquid is avoided.

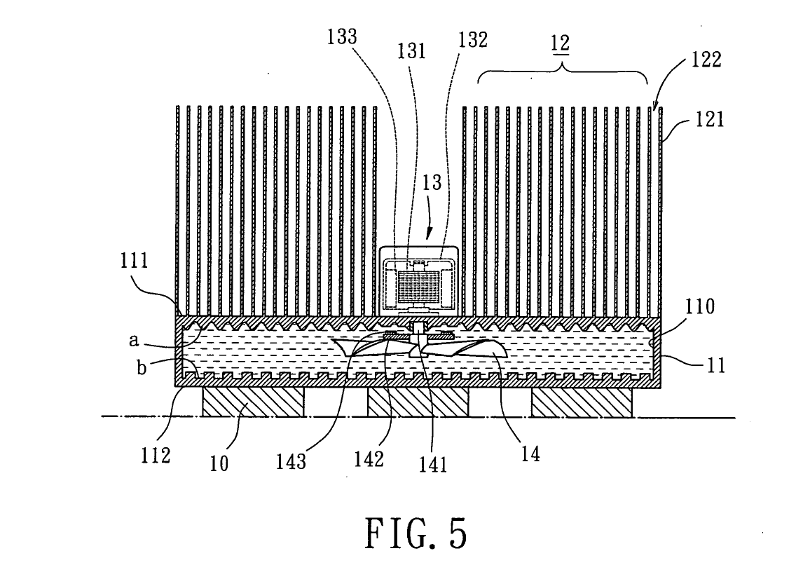

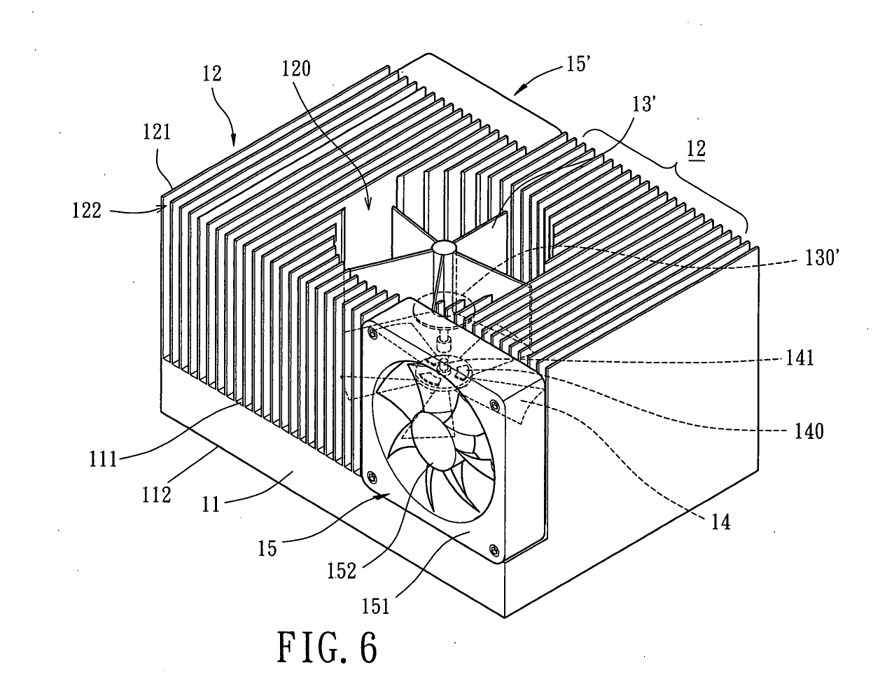

FIG. 5 shows a second embodiment of the composite heat-dissipating module in accordance with the present invention. Compared to the first embodiment, at least one wall face a, b of the base 11 in this embodiment includes regular or irregular concave portions and/or convex portions to increase the heat exchange area between the wall face a, b and the heat-conducting liquid. By this arrangement, even though the compartment 110 is not full with the heat-conducting liquid, the level of the heat-conducting liquid may come in contact with the concave portions and convex portions of the wall face a, b, assuring heat transfer from the heat-conducting liquid to the wall face a, b and the fin units 12. Thus, the second embodiment not only possesses the advantages of reduced overall height and increased overall area obtained from lateral disposition of the horizontal air-feeding units 15 but also provides higher heat-exchange efficiency and a different stirring manner.

FIG. 6 shows a third embodiment of the composite heat-dissipating module in accordance with the present invention. Compared to the first and second embodiments, at least one fin unit 12 is mounted on the top face 111 of the base 11 in this embodiment. The at least one fin unit 12 defines a space 120 for mounting a driving member 13′. Further, at least two horizontal air-feeding units 15 and 15′ are respectively mounted on opposite first and second sides of the at least one fin unit 12. The horizontal air-feeding unit 15 drives an airflow to flow from the second side to the first side of the at least one fin unit 12 whereas the horizontal air-feeding unit 15 drives an airflow to flow from the first side to the second side of the at least one fin unit 12. Preferably, the horizontal air-feeding units 15 and 15′ are located at diagonal positions or not aligned with each other. Thus, the airflows driven by the horizontal air-feeding units 15 and 15′ flow through different heat-dissipating channels 122 of the at least one fin unit 12, avoiding mutual interference of the lateral horizontal airflows. By such an arrangement, at least two lateral horizontal airflows are provided, allowing flexible designs in the airflow directions to meet heat-dissipation needs of various electronic devices.

Still referring to FIG. 6, the driving member 13′ is an impeller of blower type or axial flow type. The driving member 13′ includes a magnet 130′ aligned with the stirring unit 14. The stirring unit 14 includes a magnet 140 aligned with the magnet 130′. When the horizontal air-feeding units 15 and 15′ operate, a portion of the lateral horizontal airflow driven by the horizontal air-feeding unit 15 flows through a portion of the space 120 and/or a portion of the lateral horizontal airflow driven by the horizontal air-feeding unit 15′ flows through another portion of the space 120. By such an arrangement, in this embodiment, at least one of the horizontal air-feeding units 15 and 15′ creates airflow to turn the driving member 13′, and the stirring unit 14 is indirectly driven by mutual magnetic attraction between the magnet 130′ on the driving member 13′ and the magnet 140 on the stirring unit 14, thereby stirring the heat-conducting liquid. By this arrangement, no electrical energy is required for driving the driving member 13′ while not reducing the speed of the horizontal air-feeding units 15 and 15′ and not adversely affecting the air-driving efficiency.

While the principles of this invention have been disclosed in connection with specific embodiments, it should be understood by those skilled in the art that these descriptions are not intended to limit the scope of the invention, and that any modification and variation without departing the spirit of the invention is intended to be covered by the scope of this invention defined only by the appended claims.

What is claimed is:

1. A composite heat-dissipating module comprising:
a base comprising a top face, a bottom face, and a compartment, the bottom face being adapted to contact with an object to be heat-dissipated, a heat-conducting liquid being received in the compartment;
at least one fin unit mounted on the top face of the base, said at least one fin unit including a plurality of fins, a heat-dissipating channel being defined between a pair of the fins adjacent to each other;
a stirring unit for stirring the heat-conducting liquid to circulate the heat-conducting liquid in the compartment; and
at least two horizontal air-feeding units mounted on at least one side of said at least one fin unit, said at least two horizontal air-feeding units providing lateral airflows into the heat-dissipating channels for dissipating heat.

2. The composite heat-dissipating module as claimed in claim 1 wherein said at least two horizontal air-feeding units are mounted to the same side of said at least one fin unit.

3. The composite heat-dissipating module as claimed in claim 2 wherein said at least two horizontal air-feeding units are mounted to different sides of said at least one fin unit and wherein the airflows driven by said at least two horizontal air-feeding units flow through different portions of said at least one fin unit.

4. The composite heat-dissipating module as claimed in claim 1 wherein said at least two horizontal air-feeding units are selected from at least one of axial flow fans and blower fans.

5. The composite heat-dissipating module as claimed in claim 1 wherein the stirring unit is mounted in the compartment.

6. The composite heat-dissipating module as claimed in claim 1 further comprising a driving member mounted on the top face of the base, the driving member indirectly driving the stirring unit.

7. The composite heat-dissipating module as claimed in claim 6 wherein the stirring unit is an impeller including a shaft rotatably coupled to an inner wall of the base and wherein the impeller is aligned with the driving member.

8. The composite heat-dissipating module as claimed in claim 6 wherein the driving member is a motor comprising a stator and a rotor, the stator including at least one coil and at least one pole plate, the rotor including at least one magnet.

9. The composite heat-dissipating module as claimed in claim 8 wherein the stirring unit comprises an actuating plate, at least one magnetically inductive member being mounted on the actuating plate and aligned with the magnet of the rotor.

10. The composite heat-dissipating module as claimed in claim 9 wherein the magnetically inductive member is made of magnetic material or magnetically conductive material.

11. The composite heat-dissipating module as claimed in claim 6 wherein the driving member is an impeller of blower type or axial flow type, the driving member including a magnet for driving the stirring unit by magnetic attraction.

12. The composite heat-dissipating module as claimed in claim 11 wherein the stirring unit is an impeller including a shaft rotatably coupled to an inner wall of the base, the impeller including a magnet aligned with the magnet on the driving member.

13. The composite heat-dissipating module as claimed in claim 11 wherein the driving unit is driven by a portion of lateral horizontal airflow driven by at least one of said at least two horizontal air-feeding units.

14. The composite heat-dissipating module as claimed in claim 11 wherein the fins define a space in which the driving unit is mounted.

15. The composite heat-dissipating module as claimed in claim 14 wherein the driving unit is driven by a portion of lateral horizontal airflow driven by at least one of said at least two horizontal air-feeding units that flows through the space.

16. The composite heat-dissipating module as claimed in claim 1 wherein at least one wall defining the compartment of the base includes a plurality of concave portions or a plurality of convex portions to increase a heat-exchange area between said at lease one wall and the heat-conducting liquid.
